(19) United States
(12) Patent Application Publication
(10) Pub. No.: US 2016/0247043 A1
(43) Pub. Date: Aug. 25, 2016

(54) Thin-film Sensing and Classification System

(71) Applicants: Warren Rieutort-Louis, Princeton, NJ (US); Tiffany Moy, Princeton, NJ (US); Zhuo Wang, Princeton, NJ (US); Naveen Verma, Princeton, NJ (US); Sigurd Wagner, Princeton, NJ (US); James C. Sturm, Princeton, NJ (US)

(72) Inventors: Warren Rieutort-Louis, Princeton, NJ (US); Tiffany Moy, Princeton, NJ (US); Zhuo Wang, Princeton, NJ (US); Naveen Verma, Princeton, NJ (US); Sigurd Wagner, Princeton, NJ (US); James C. Sturm, Princeton, NJ (US)

(21) Appl. No.: 15/048,786

(22) Filed: Feb. 19, 2016

Related U.S. Application Data
(60) Provisional application No. 62/118,118, filed on Feb. 19, 2015.

(51) Int. Cl. G06K 9/62; H04N 5/225; H04N 5/232

(52) U.S. Cl. CPC G06K 9/6256; G06K 9/6267; H04N 5/23229; H04N 5/2253

(57) ABSTRACT

Large-area electronics (LAE) enables the formation of a large number of sensors capable of spanning dimensions on the order of square meters. An example is X-ray imagers, which have been scaling both in dimension and number of sensors, today reaching millions of pixels. However, processing of the sensor data requires interfacing thousands of signals to CMOS ICs, because the implementation of complex functions in LAE has proven unviable due to the low electrical performance and inherent variability of the active devices available, namely amorphous silicon (a-Si) thin-film transistors (TFTs) on glass. Envisioning applications that perform sensing on even greater scales, disclosed is an approach whereby high-quality image detection is performed directly in the LAE domain using TFTs. The high variability and number of process defects affecting both the TFTs and sensors are overcome using a machine-learning algorithm, known as Error-Adaptive Classifier Boosting (EACB), to form an embedded classifier. Through EACB, the high-dimensional sensor data can be reduced to a small number of weak-classifier decisions, which can then be combined in the CMOS domain to generate a strong-classifier decision.

### CROSS-REFERENCE TO RELATED APPLICATIONS

The present application claims priority from U.S. Provisional Application No. 62/118,118, filed Feb. 19, 2015, which is incorporated herein by reference as if set forth in full below.

### STATEMENT REGARDING FEDERALLY SPONSORED RESEARCH

This invention was made with government support under Grants No. ECCS1202168 and CCF1218206 awarded by the National Science Foundation and with support under Subaward #2013-01024-04 from the University of Illinois at Urbana-Champaign (Prime MARCO #2013-MA-2385) under Grant No. HR0011-13-0002 awarded by the Department of Defense—DARPA. The government has certain rights in the invention.

### BACKGROUND OF THE INVENTION

I. Field

The present invention relates to a system for classifying and recognizing shapes, objects, or signals using large sensor arrays and certain adaptive machine-learning classification algorithms.

II. Background

In present imaging systems, computationally-intensive tasks, such as classification, are achieved using high-performance electronics which take as input, large volumes of raw data from the sensor array. This requires thousands of costly interfaces to many electronic chips. The disclosed approach overcomes this by performing the learning tasks in the same technological platform as the sensors, allowing a reduction of the number of interfaces to subsequent computational blocks.

Typical sensor array implementations require the ability to manufacture the highest quality devices and sensors, posing strong requirements on fabrication. The disclosed approach allows for significant processing variability by using a machine learning algorithm that iteratively trains low performance classifier units (with faulty devices) and combines their ensemble outputs into a single learning decision.

### SUMMARY OF THE INVENTION

The present invention addresses the issues discussed above by providing a sensing and classification system that addresses the increasingly large number of sensor outputs in detection technology by embedding low-computational-overhead classifier circuitry with large sensor arrays.

An exemplary embodiment of the invention provides a thin-film sensing and classification system, comprising: a plurality of thin-film image sensors; a plurality of thin-film weak classifier circuits, each said classifier circuit coupled to each of said thin-film image sensors; a plurality of threshold comparison circuits; a weighted voter circuit, said weighted voter circuit coupled to said weak classifier circuits via said plurality of threshold comparison circuits; and a summing circuit coupled to each of said weighted voter circuits, wherein said summing circuit is configured to generate a strong classifier decision output.

Another exemplary embodiment of the invention provides a thin-film image sensing and classification system, comprising a plurality of thin-film sensors; a backplane on which said thin-film sensors are mounted; a plurality of thin-film electronic classifier circuits embedded on said backplane and coupled to said plurality of thin-film sensors; and a computational unit coupled to said classifier circuits.

Another exemplary embodiment of the invention provides a sensing and classification system, comprising a plurality of sensors, each said sensor generating an output; a plurality of weak classifiers, wherein each said weak classifier is connected to said output of each sensor of said plurality of sensors; a weighted voter, wherein said weighted voter is connected to said plurality of weak classifiers; and a summing circuit coupled to said weighted voter, wherein said summing circuit is configured to generate a strong classifier decision output.

Additionally, some embodiments of the invention include linear weak classifiers comprising thin-film weak classifier circuits, each such thin-film weak classifier circuit comprising a plurality of subunits, each said subunit comprising a plurality of branches, and each said branch comprising two series connected thin-film transistors; and, wherein each said weak classifier generates differential outputs, and said weak classifier differential outputs are provided to said threshold comparison circuits. Other embodiments of the invention include a trainer circuit, wherein said trainer circuit is coupled to the output of a summing circuit, wherein said trainer circuit is configured to provide feedback to weak classifier circuits and to a weighted voter circuit. In some embodiments of the invention, there is at least one thin-film transistor in each branch of each subunit of each weak classifier, and said thin-film transistor is a variable strength thin-film transistor, wherein a trainer circuit is configured to provide feedback to each said weak classifier circuit via application of a programming voltage to each said variable strength thin-film transistor.

In some embodiments of the invention, the weak classifiers are implemented as decision-trees.

In some embodiments of the invention, a trainer circuit employs an Adaptive Boosting (AdaBoost) machine-learning algorithm to provide bias weights to weak classifier circuits.

### BRIEF DESCRIPTION OF THE DRAWINGS

For a further understanding of the nature and objects of the present invention, reference should be had to the following description taken in conjunction with the accompanying drawings in which like parts are given like reference numerals.

FIG. 1 is a block diagram of a DDHR system for embedded sensing.

FIG. 2 is a block diagram showing the architecture of an error-adaptive classifier boosting system.

FIG. 3 is a block diagram showing the implementation of an error-adaptive classifier boosting system utilizing decision-tree weak classifiers.

FIG. 4 illustrates an exemplary x-ray imaging system which includes embedded weak classifier circuits.

FIG. 4a illustrates a cutaway of an exemplary thin-film photoconductor.

FIG. 4b shows a plan view of an exemplary thin-film photoconductor.

FIG. 5 is a graph showing the I-V response to different thin-film sensors in different lighting conditions.

FIG. 6 is a graph showing the voltage output of different thin-film sensors in certain lighting conditions, and also shows the response of “broken” sensors.

FIG. 7 is an algorithmic block diagram of an error-adaptive classifier boosting system.

FIG. 8 is a circuit diagram showing an implementation of an error-adaptive classifier boosting system using thin-film transistors.

FIG. 8b is comprised of a circuit diagram showing an exemplary programmable thin-film transistor, and further includes a graph demonstrating the multiplication transfer function achieved by a two-TFT branch, along with measurement bars illustrating variations across 15 instances.

FIG. 9 is comprised of several graphs demonstrating the changes to thin-film transistor characteristics via the application of training voltages, and further includes information from certain test configurations.

FIG. 10 is a series of graphs showing the performance of an implementation of an error-adaptive classifier boosting system using thin-film transistors with respect to several different shapes.

FIG. 11 shows an experimental setup and summarizes the associated classifier system performance.

FIG. 12 shows different views of micrographs of exemplary fabricated a-Si photoconductors and TFT weak classifiers.

FIG. 13 shows a testing dataset and different levels of ambient lighting used during testing.

FIG. 14 is a series of graphs showing the performance of an implementation of an error-adaptive classifier boosting system using thin-film transistors with different numbers of weak classifiers.

FIG. 15 shows a cross-sectional view of an exemplary thin-film transistor programmable element, along with graphs showing certain programmability information.

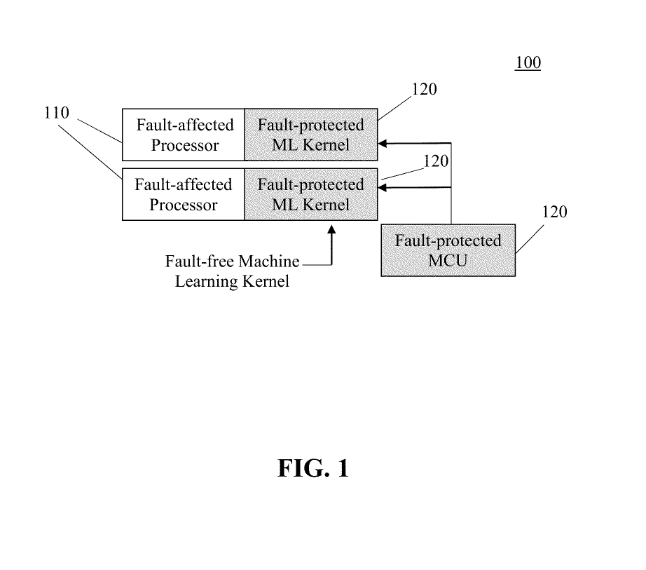

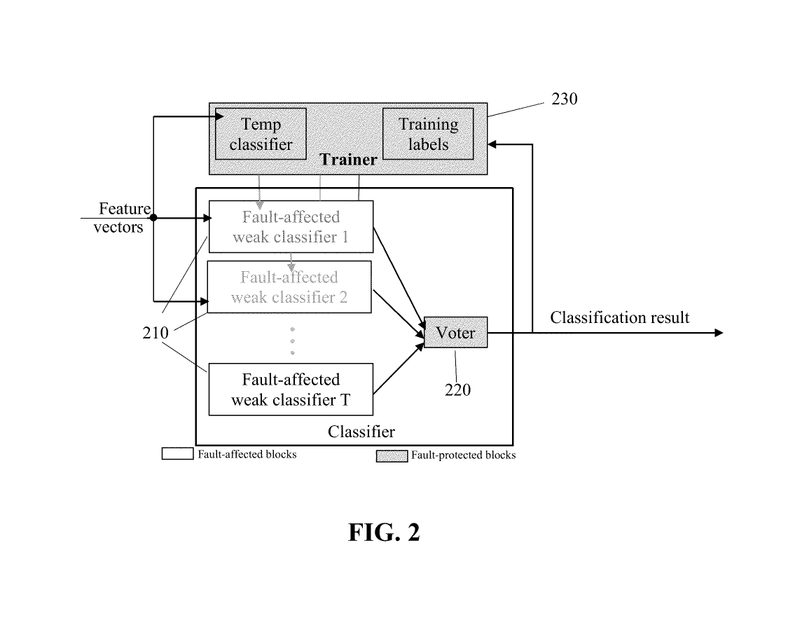

The images in the drawings are simplified for illustrative purposes and are not depicted to scale. Within the descriptions of the figures, similar elements are provided similar names and reference numerals as those of the previous figure(s). Where a later figure utilizes the same element or a similar element in a different context or with different functionality, the element is provided a different leading numeral representative of the figure number (e.g., 1xx for FIG. 1 and 2xx for FIG. 2). The specific numerals assigned to the elements are provided solely to aid in the description and are not meant to imply any limitations (structural or functional) on the invention.

The appended drawings illustrate exemplary configurations of the invention and, as such, should not be considered as limiting the scope of the invention that may admit to other equally effective configurations. It is contemplated that features of one configuration may be beneficially incorporated in other configurations without further recitation.

### DETAILED DESCRIPTION

The word “exemplary” is used herein to mean “serving as an example, instance, or illustration.” Any configuration or design described herein as “exemplary” is not necessarily to be construed as preferred or advantageous over other configurations or designs.

Technological scaling and system-complexity scaling have dramatically increased the prevalence of hardware faults, to the point where traditional approaches based on design margining are becoming inviable. The challenges are exacerbated in embedded sensing applications due to the severe energy constraints. Given the importance of classification functions in such applications, this disclosure presents an architecture for overcoming faults within a classification processor. The approach exploits machine learning for modeling not only complex sensor signals but also error manifestations due to hardware faults. Adaptive boosting is exploited in the architecture for performing iterative data-driven training. This is used to enable the effects of faults in preceding iterations to be modeled and overcome during subsequent iterations.

Machine-learning algorithms are becoming increasingly important in embedded sensing applications. Machine learning enables efficient construction of data-driven models for analyzing signals that are too complex to otherwise model analytically. Given the prominence of recognition/detection functions, frameworks for classification and regression are of particular importance. Recently, studies have also begun to expose the potential that machine learning brings for overcoming non-idealities (technological faults, transistor variations, etc.) affecting the hardware platform itself. An approach known as data-driven hardware resilience (DDHR) enables very high levels of fault tolerance by utilizing a machine-learning stage to model the variances in embedded data caused not only due to the application signals but also due to hardware faults. However, in existing DDHR implementations, the machine-learning stage is explicitly required to be fault protected. For example, two system demonstrations showed that by protecting 7% to 30% of the hardware, performance essentially equivalent to a fault-free system could thus be achieved even with faults affecting 0.02% to 3% of the circuit nodes in the rest of the architecture (resulting in bit error rates of 20-50%). The problem is that the complexity of machine-learning kernels scales strongly with the models required, making their impact on a system substantial, particularly as the hardware platform and application signals both scale in complexity. The present invention is based on an architecture for the machine learning stage (classifier) that is itself allowed to be greatly affected by faults. The presented approach, termed error-adaptive classifier boosting (EACB), takes advantage of adaptive boosting (AdaBoost), which is an iterative training algorithm applied to weak classifiers.

The following is a discussion of DDHR, which is introduced to illustrate the powerful opportunities that machine learning enables for overcoming hardware faults via data-driven training. Then AdaBoost is introduced, which the present invention exploits in a machine-learning kernel that is itself allowed to be highly fault prone, substantially expanding the concept of DDHR.

Data Driven Hardware Resilience (DDHR).

The key to DDHR is utilizing data from an instance of fault affected hardware to construct a model for classification or regression. The resulting model is called an error-aware model; while, generally, faults occur randomly and cause unpredictable errors, the error-aware model represents the data statistics in the presence of the particular occurring faults. FIG. 1 shows a DDHR system 100 for embedded sensing. The fault-affected blocks 110 (in white) include feature extraction processors. The fault-protected blocks 120 (in grey) include a support-vector machine (SVM) classifier and a microcontroller for applying and training the model, respectively. Training, however, requires labels in addition to error-affected data. The labels are achieved entirely within the architecture by implementing a temporary error-free system on the microcontroller, which can thus employ a generic model not requiring training to particular error statistics; since training is performed infrequently, the temporary system has minimal impact on the system. While the labels, thus computed, are estimates rather than ground truths, they enable model training that converges to give performance up to that of a fault-free system.

An important characteristic of DDHR is that, thanks to data-driven training, system performance is not limited by the rate or magnitude of errors, but rather more fundamentally by the level of information retained in the error-affected data. A primary limitation of DDHR, however, is the need for substantial fault-protected hardware (machine-learning stages), whose impact increases with increasing system and application-data complexity due to the need for higher-order models. Accordingly, the present invention aims to extend the error-modeling capabilities within the classifier hardware itself. For this we leverage the AdaBoost algorithm, which uses multiple weak classifiers. We show that these enable an architecture wherein high-levels of faults can be overcome through iterative training.

Adaptive Boosting (AdaBoost).

AdaBoost is a machine-learning algorithm that aims to achieve a highly-accurate classifier through a combination of T weak classifiers. The output of a weak classifier is (arbitrarily) weakly correlated with the true class. The algorithm iteratively trains the weak classifiers, establishing both a decision rule and a weight for each iteration. The final hypothesis is then derived from weighted voting over the weak classifiers. So long as each weak classifier performs slightly better than random guessing, the performance is guaranteed to fit a training set perfectly, given enough iterations. However, an important consideration that remains is choosing a weak classifier that results in good generalization over testing data.

A common and effective weak classifier used with AdaBoost is the decision tree. Each node of the tree is a statement about the feature vector being classified, thus determining the next node to be considered, eventually yielding a classification result at the leaf nodes. In practical weak-classifier implementations, as in the case of a decision tree, performance is typically limited by an inadequate decision rule for fitting the training data. In the present invention, the concept is extended, with weak-classifier performance also being limited by errors due to hardware faults. We focus on decision trees, not only because they are empirically shown to be effective weak classifiers, but also because they can be mapped to an implementation that substantially mitigates the amount of control circuitry, thereby minimizing the fault-protected hardware required. As we discuss below, other classifiers may be used besides decision trees, such as linear classifiers.

Additionally, decision trees bring the benefit of comparatively simple training algorithms. Nonetheless, training remains substantially more complex than real time classification. To perform training at run time (with limited data), we develop an algorithm that leverages the idea of the FilterBoost algorithm, but while also substantially reducing the computations and embedded memory required. This thus minimizes the overhead of an embedded trainer.

Error-Adaptive Classifier Boosting.

The aims of EACB are as follows: (1) strong classification, with minimal hardware energy and complexity, based on scalable data driven training; (2) high classifier performance in the presence of very high fault rates; (3) need for minimal fault-protected hardware, both for classification and training. The following subsections describe the EACB architecture and implementation.

EACB Architecture.

EACB is based on the following recognition. A stage whose output function is determined by data-driven training over its set of inputs raises the possibility of overcoming faults in the preceding stages. The errors from faults in the preceding stages can be viewed simply as altering the statistics of the resulting data. EACB uses AdaBoost, wherein the hypotheses generated by preceding weak classifiers are taken as inputs during data-driven training of subsequent iterations. The architecture of EACB is shown in FIG. 2, comprising the following: (1) T fault-affected weak classifiers 210, implemented as decision trees; (2) a fault-protected voter 220, implemented as a T input signed adder where the inputs and sign bits correspond to the classifier weights and outputs, respectively; and (3) a fault-protected trainer 230, which is required infrequently and may be implemented via a microcontroller. Using AdaBoost, the weak classifiers effectively enable data-driven training in successive stages. Consequently, each iteration performs training to the statistics of the hypotheses generated by the preceding weak classifiers in the presence of their faults. However, as in the case of DDHR, training the weak classifiers requires training labels. A temporary, fault-free classifier is thus implemented in software on the microcontroller to generate estimated labels (as in DDHR).

Weak Classifiers for Maximizing Fault Tolerance.

The choice and implementation of the weak classifiers strongly influences overall performance (i.e., tradeoff between accuracy and diversity), training complexity, and achievable level of fault tolerance. Among the various classifiers that have been considered for boosting (support vector machines, neural networks, decision trees), decision trees enable reduced training complexity and, as described below, enable a specialized implementation that offers high fault tolerance within EACB. A critical aspect for fault tolerance is a circuit's control-path implementation. While data-path faults alter the output statistics, the probability of retaining some correlation with class information remains high, as required of weak learners in AdaBoost. However, control-path faults can result in degenerate outputs, inadequate for even a weak classifier.

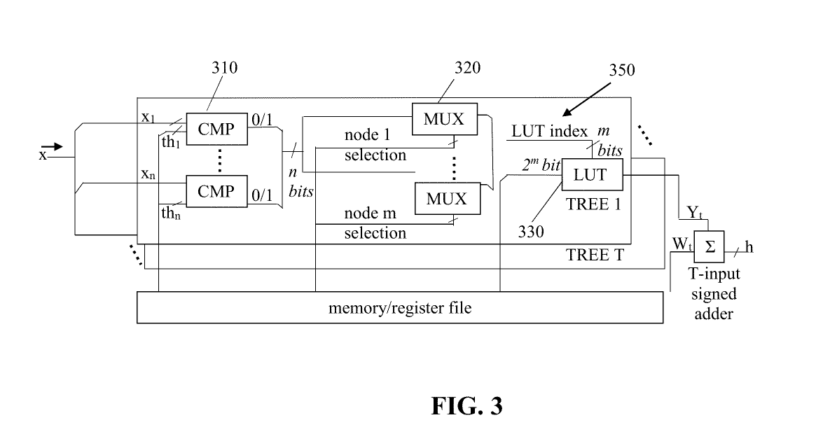

FIG. 3 shows the implementation developed for the decision-tree weak classifiers, with the aim of minimizing the control path while retaining the programmability needed for EACB training. The implementation consists of three stages. First, a node for each of the n features is implemented by digital comparison (CMP) 310 with a threshold derived from model training; this has the benefit of immediately reducing the n features to n bits, corresponding to the node outputs. Second, m n-to-1 multiplexers (MUX) 320 select the nodes and their locations to include in the tree 350, as also derived from model training. The number of nodes 310 is thus limited to m. Third, the m multiplexer outputs are used as the index to a look-up table (LUT) 330, whose entries are also determined from training, thereby deriving the single-bit classifier output. In this implementation, only the number of tree nodes is limited.

Low-Overhead Embedded Trainer.

The challenge with embedded training is the need for a large training set (to address diversity), thus making memory requirements excessive. For example, a standard training algorithm in an exemplary system could require 5,000 feature vectors, corresponding to 420 kB of memory. We have developed a training algorithm that reduces the training data memory through two approaches: (1) feature selection based on a learner metric; and (2) iterative training with small but distinct training sets to mitigate generalization error. For feature selection, each feature is ranked based on its number of occurrences in the decision trees formed during an offline training phase (i.e., for the temporary classifier of FIG. 2); the most commonly occurring features are selected as being the most informative for classification. For enabling small, distinct training sets, the idea of FilterBoost is leveraged, wherein new training data is selected for each iteration. However, for run-time training, where the only data available is being acquired on line, we use all the acquired data to form the training set. This in fact is critical for reducing computational complexity, by avoiding the need to derive complex selection criteria, thereby reducing the number of clock cycles of the microcontroller by a factor of 10×.

Test System.

To evaluate EACB, we performed hardware experiments using an FPGA. This permits error injection at desired rates and in a randomized manner, enabling controlled characterization. The experimentation details of the embodiment implementing a decision tree classifier are provided below.

Prototype Testing and Potential Application.

For experimental demonstration and evaluation, we applied EACB to a system for EEG-based detection of epileptic seizures. The system consists of a feature-extraction stage and a classifier (which employs EACB). The features correspond to the spectral-energy distribution of 2 EEG channels, across 7 frequency bins, over three 2-second epochs, giving a total of 42 features. The classifier consisted of the architecture in FIG. 2, with the trainer implemented via an embedded Open MSP microcontroller running software for training and label estimation. EEG data for testing (10,000 seconds) was obtained from the MIT-CHB seizure database. The decision-tree weak classifiers were implemented in RTL, using the topology in FIG. 3. As noted, the maximum number of nodes in the tree was set by the topology. For design exploration, we considered three cases: (1) 7-node trees; (2) 4-node trees; and (3) 1-node trees (i.e., stumps). The metrics for evaluation included the following: (1) the fault-rates tolerable while maintaining application-level performance; (2) the amount of fault-affected and fault-protected hardware; and (3) the complexity of the trainer.

Alternative Embodiment: Image Classification using TFT Classifier.

As an alternative to the embodiment described above, a different embodiment was also tested in connection with image classification. The following is a description of said alternative embodiment and configuration.

Large-area electronics (LAE) enables the formation of a large number of sensors capable of spanning dimensions on the order of square meters. An example is X-ray imagers, which have been scaling both in dimension and number of sensors, today reaching millions of pixels. However, processing of the sensor data requires interfacing thousands of signals to CMOS ICs, because implementation of complex functions in LAE has proven unviable due to the low electrical performance and inherent variability of the active devices available, namely amorphous silicon (a-Si) thin-film transistors (TFTs) on glass. Envisioning applications that perform sensing on even greater scales, this work presents an approach whereby high-quality image detection is performed directly in the LAE domain using TFTs. The high variability and number of process defects affecting both the TFTs and sensors are overcome using a machine-learning algorithm known as Error-Adaptive Classifier Boosting (EACB) to form an embedded classifier. Through EACB, we show that high-dimensional sensor data can be reduced to a small number of weak-classifier decisions, which can then be combined in the CMOS domain to generate a strong-classifier decision.

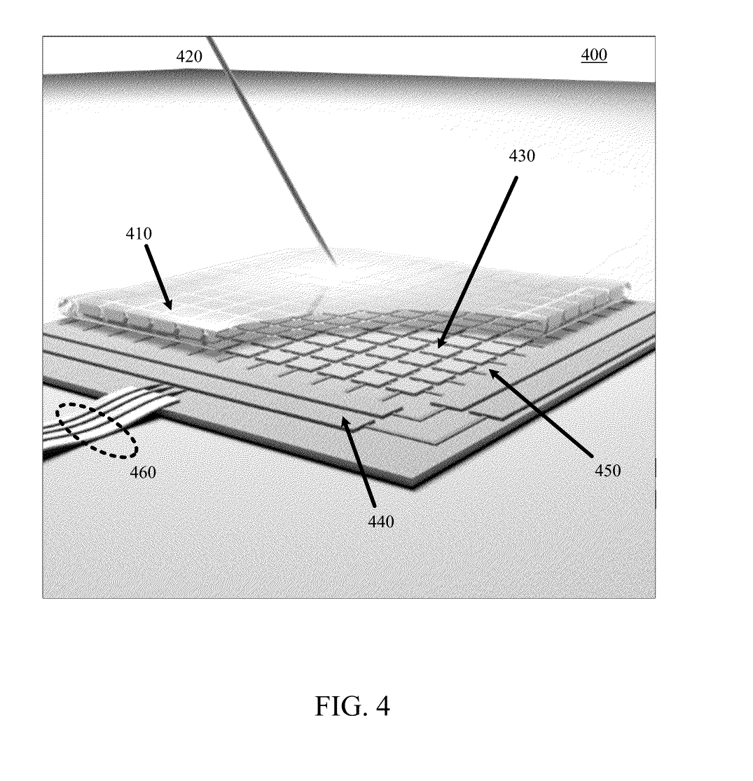

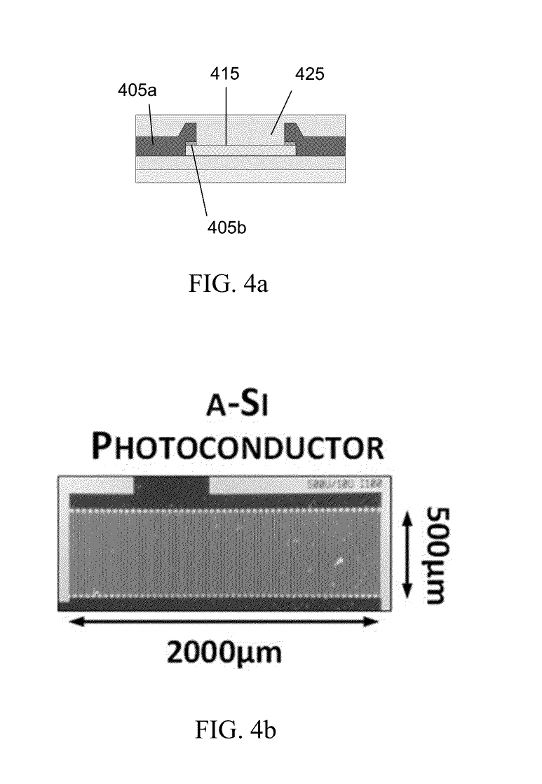

To demonstrate the concept, we developed the system in FIG. 4. An X-ray imager 400 typically consists of a thin-film scintillator 410 for converting X-rays 420 to photons. Imager 400 further comprises an underlying array of photoconductors 430 formed from undoped a-Si, producing a large number of sensor outputs 450, which feed an embedded thin-film classifier 440, formed from a-Si TFTs. As can be seen, the use of embedded classifiers results in a smaller number of classifier outputs 460 as compared to the large number of sensor outputs 450. FIG. 4a shows a cutaway of an exemplary photoconductor 430, comprising: S/D Contact point 405a, comprising 50 nm Cr; S/D Contact point 405b, comprising 30 nm n⁺ a-Si:H; active region 415, comprising 150 nm a-Si:H; and, passivation 425, wherein said passivation comprises 280 nm SiNₓ. FIG. 4b shows a plan view of an exemplary photoconductor 430.

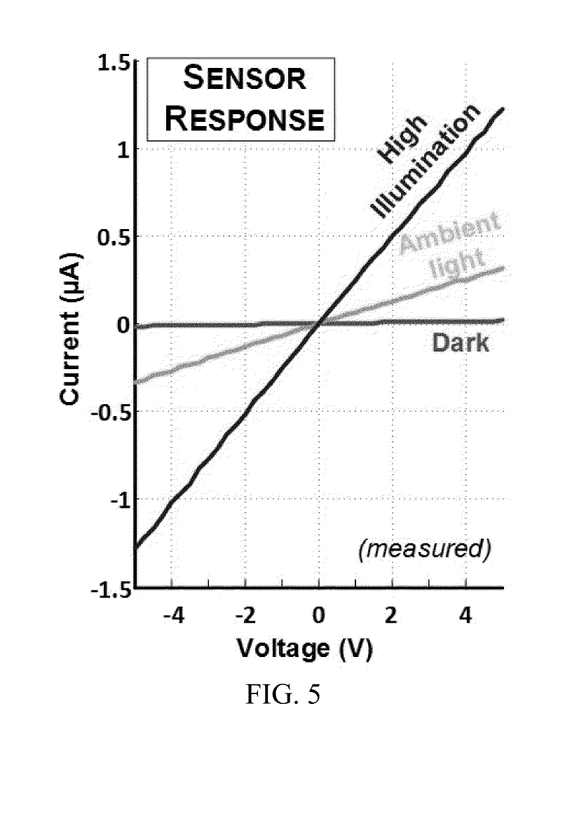

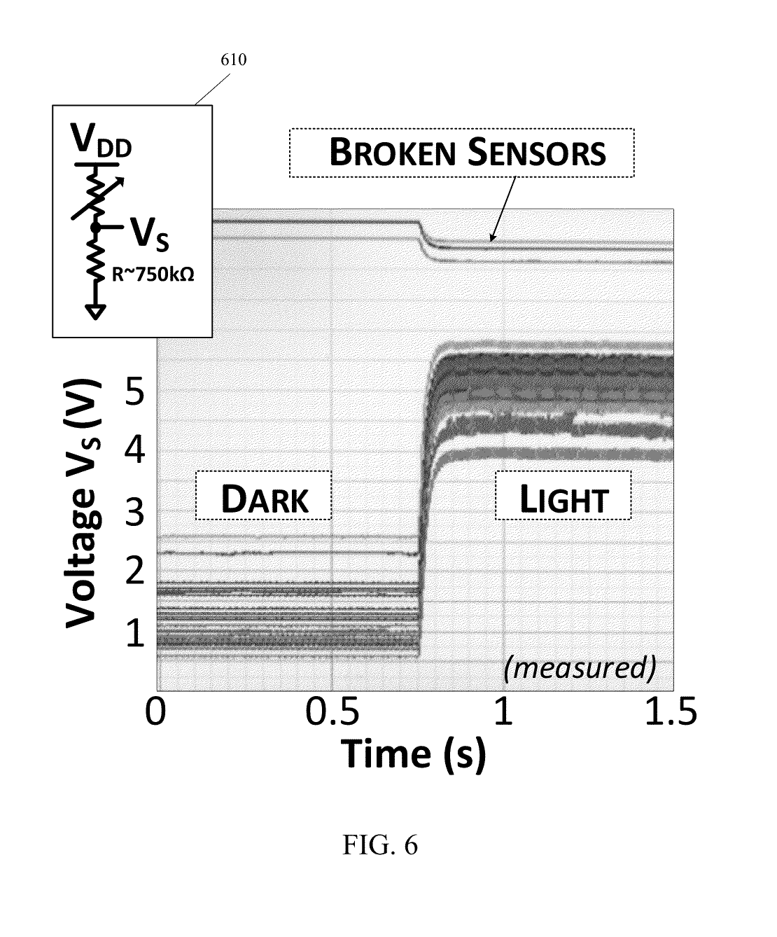

The photoconductors 430 exhibit strong but non-uniform conductivity change in response to illumination, as shown in the measured I-V characteristic in FIG. 5. Configured as the leg of a voltage divider (see insert 610 on FIG. 6), each photoconductor 430 provides an output voltage Vs, shown in response to light and dark 410 conditions (see FIG. 6). Measurements show substantial variability and even failure of some sensors (FIG. 6). In our tests, the present invention overcomes issues such as failed sensors, as well as non-idealities in the TFT classifiers, demonstrating the classification of five shapes with performance at the level of an ideal MATLAB-implemented strong classifier.

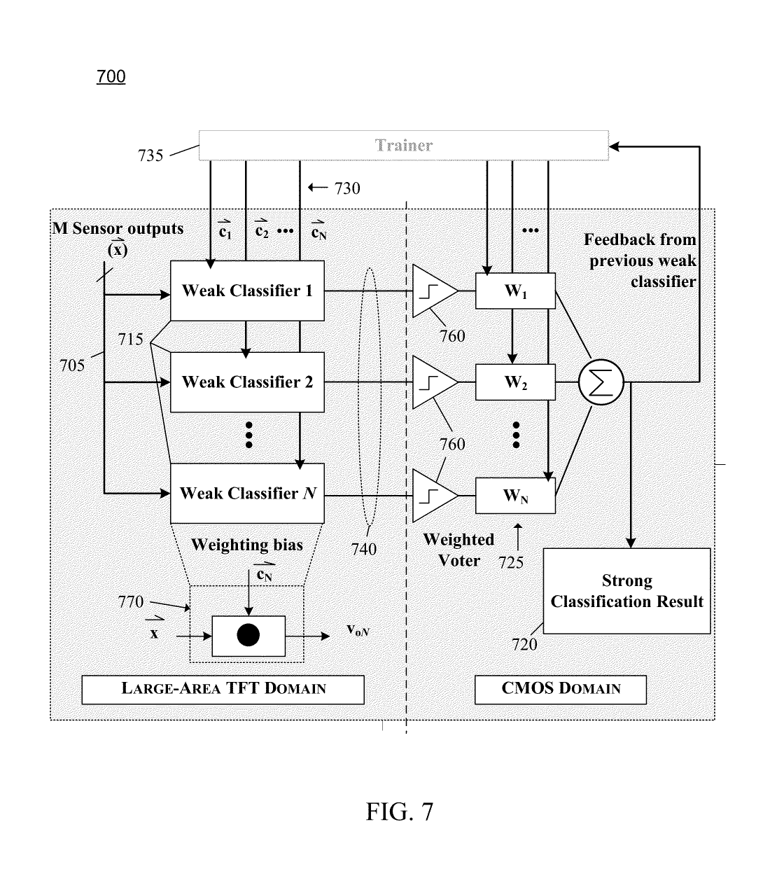

FIG. 7 shows the algorithmic block diagram of the EACB classifier 700. The outputs 740 from N weak classifiers 715, implemented using TFTs, are provided to a weighted voter 725 (in the CMOS domain) to produce a strong-classifier output 720. In machine learning, a weak classifier is defined as one that is restricted in its ability t fit arbitrary data distributions, often resulting in substantial classification errors, whereas a strong-classifier is one that can be trained to fit arbitrary distributions. The key benefit of EACB is that the performance required of the weak classifiers is very low, namely only marginally better than 50/50 guessing. This enables simple weak-classifier implementations based on TFTs. In the system shown in FIG. 7, the weak classifiers 715 are nominally implemented as linear classifiers. As shown (in callout 770), each linear classifier, involves dot-product multiplication between an input-signal vector \vec{x}₁ whose elements correspond to the M sensor outputs 705, and a classification vector \vec{c}_{g}, whose elements correspond to weighting biases 730 provided from one-time training via trainer 735. The dot-product result is then compared to a threshold by threshold comparison circuits 760 for binary classification. Recent work has shown that weak-classifier errors due to hardware imperfections can be overcome without the need to explicitly characterize or model the imperfections. This is because EACB performs weak-classifier training iteratively, enabling the errors from previous weak classifier iterations to be fed back and compensated for during training of subsequent iterations. In our system demonstration, this one-time training by trainer 735 is performed offline; however, the training algorithm can be implemented in an embedded CMOS IC (as discussed in Z. Wang, R. Shapire, N. Verma, “Error-Adaptive Classifier Boosting (EACB): Exploiting Data-Driven Training for Highly Fault-Tolerant Hardware,” IEEE Intl Conf. on Acoustics, Speech and Signal Processing, pp. 3884-3888, May 2014), with the classification vectors (\vec{c₁} . . . \vec{c}_{N}) from N iterations of training provided through, for example, a low-speed serial interface (such as that discussed in T. Moy, et al., “Thin-Film Circuits for Scalable Interfacing Between Large-Area Electronics and CMOS ICs,” Device Research Conf., pp. 271-272, June 2014.). In our exemplary implementation, the number M, of sensor outputs 705, is 36, and number N, of weak classifiers 715, is 2 to 5, demonstrating that a substantial reduction of the raw sensor signals can be achieved.

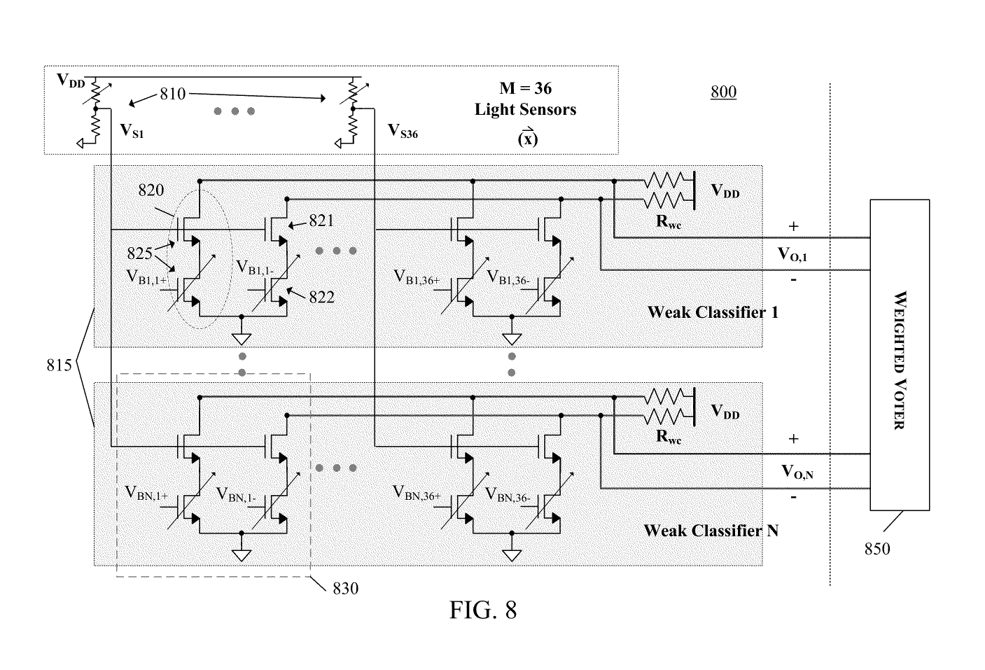

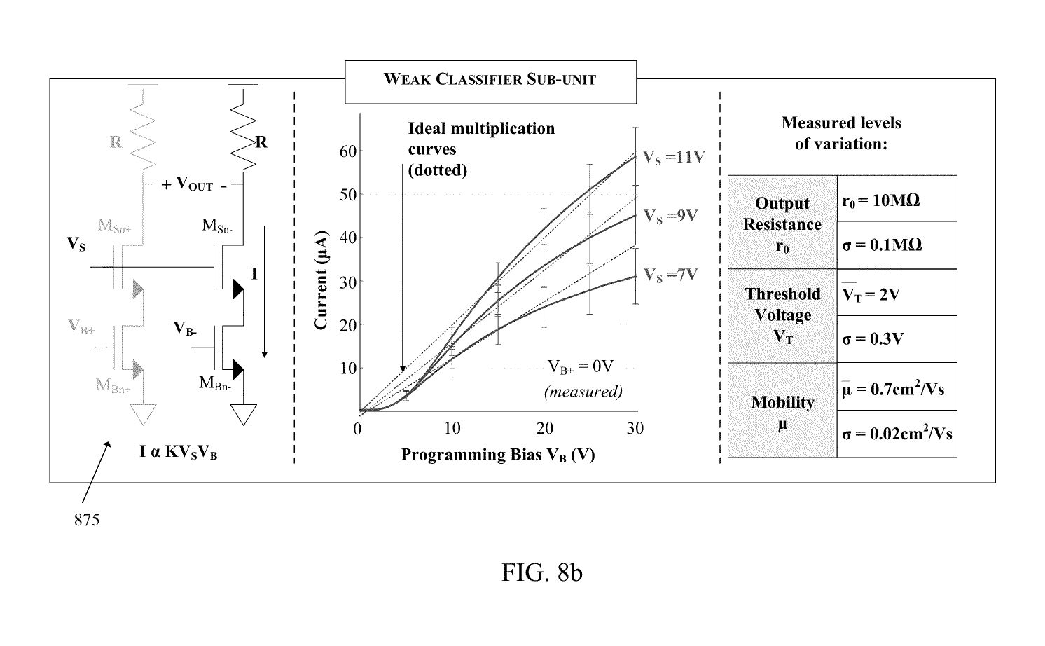

FIG. 8 shows an exemplary implementation of the TFT-based classifier discussed above, which processes the sensor outputs V_{S,1-36} using the weighting biases V_{B, 1-36,1-N} (these are realized via programmable TFTs, as described below). More specifically, TFT-based classifier 800 comprises M light sensors 810 (where M is equal to thirty-six in the embodiment shown in FIG. 8). The output of said light sensors are fed into N weak classifiers 815, where the element-wise multiplication required within the dot product is implemented as the output current from a branch 820 of two series-connected TFTs 825. In an exemplary embodiment, each branch 820 comprises a TFT 821 and a variable strength TFT 822 (and, as shown in FIG. 8, and as is discussed further below, the variable strength TFTs 822 a method by which the biases may be imparted via training).

Each weak classifier 815 is comprised of a series of M (here thirty-six) subunits 830, where each subunit 830 is comprised of two branches 820, where said branches 820 in a given subunit 830 are configured to implement pseudo-differential outputs, enabling multiplication by positive and negative weighting biases, as required from training. The summation required within the dot product is implemented by combining the branch currents within a weak classifier through a load resistor R_{WC}. The resulting differential weak-classifier outputs V_{O,1-N} can be provided to a CMOS IC (such as weighted voter 850) for threshold comparison and weighted voting, which is found to be somewhat more sensitive to computational errors.

FIG. 8b shows the multiplication transfer function achieved by a two-TFT branch (where subunit 875 is representative of the subunits 830 comprising the various weak classifiers 815), along with measurement bars illustrating variations across 15 instances. Both substantial variation and deviation from the ideal multiplication transfer function is observed. Nevertheless, as shown below, the system is able to achieve strong-classifier performance.

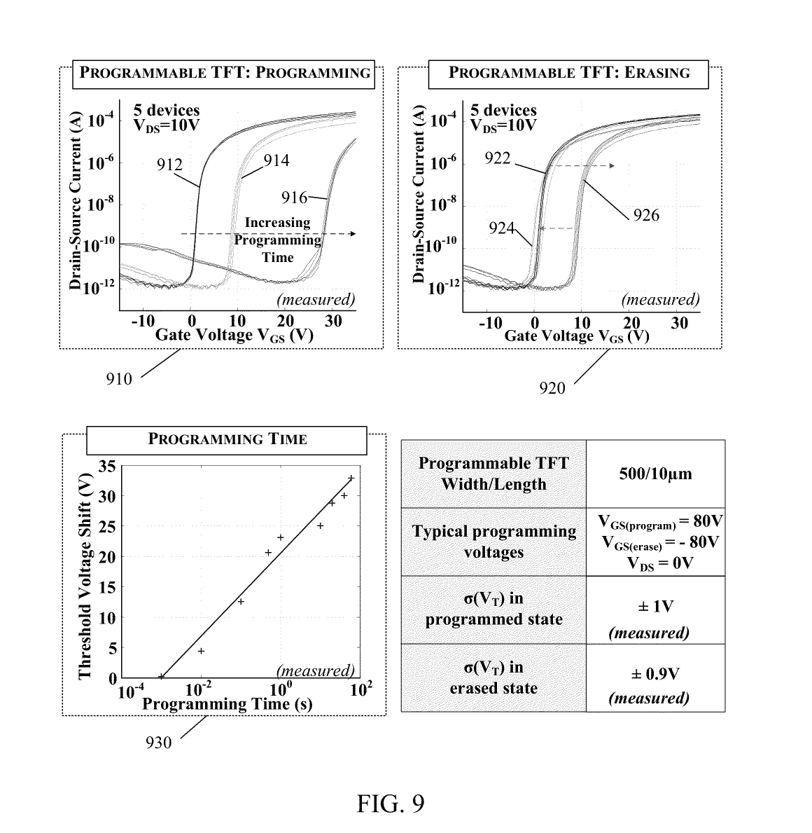

The programmable weighting biases V_{B, 1-36,1-N} of classifier 800 can be implemented by a range of thin-film memory architectures/devices. FIG. 9 shows the approach used in the embodiment shown in FIG. 8. Deliberate threshold voltage shifting is employed in connection with a conventional a-Si TFT due to charge trapping in the silicon nitride dielectric, which can be induced (removed) by high positive (negative) gate electric field. Programming a threshold voltage shift in the range of 0-30V (as required from weak-classifier training) is accomplished by applying a gate-source programming/erasing voltage of 80V for 1 ms-100s. The programmable TFT is chosen to be the lower device within the multiplier branches (e.g., variable strength TFT 822) to ease application of the programming voltage. Reliable threshold voltage shifting is achieved with respect to programming time, with a measured standard deviation <1.0 V. Experiments explicitly applying random variation in V_{B, 1-36,1-N} with σ of 1.5 V suggest that this level of variation is robustly tolerated. While the approach used incurs long programming times, optimizations of charge traps in the gate nitride have shown that these times can be substantially reduced.

Graph 910 shows changes to TFT characteristics as programming voltages are applied for increasing amounts of time, where plot 912 shows the TFT's original state, plot 914 shows the TFT's state after 10 ms of application of programming voltage (e.g., 80 V), and plot 916 shows the TFT's state after 20 ms of application of programming voltage.

Graph 920 shows changes in TFT characteristics after first programing, and second erasure of said programming, where plot 922 shows the TFT's original state, plot 924 shows the TFT's state after 10 ms of application of programming voltage (e.g., 80 V), and plot 926 shows the TFT's state after 10 ms of application of erasure voltage (e.g., −80 V).

Graph 930 shows the changes in TFT threshold voltage as a function of programming time.

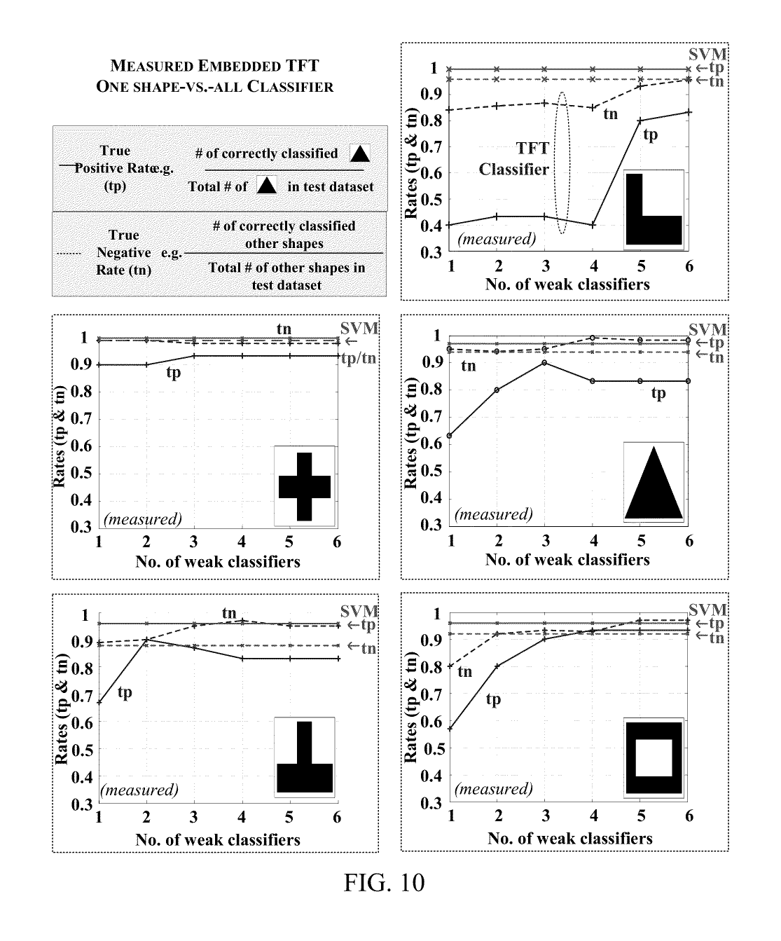

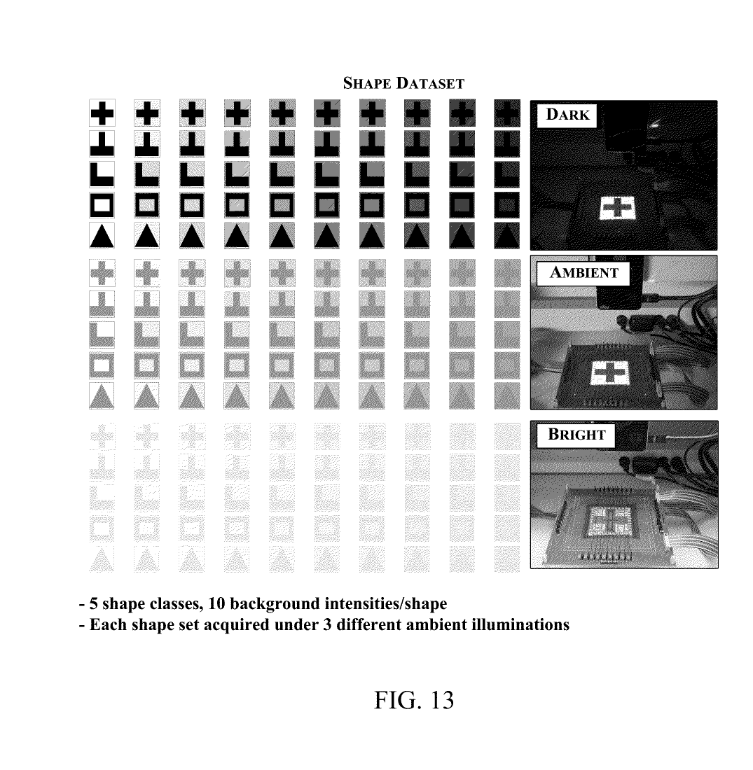

To demonstrate system functionality and performance, we performed image classification of five shapes (cross, tee, el, triangle, ring—examples of each are shown, for example, in FIG. 10) by training the system in each case as a one-versus-all classifier. The a-Si 6×6 photoconductor sensor array and TFT weak classifiers used in said test were both fabricated on glass substrates at process temperatures <180° C. (separated samples are fabricated to facilitate testing). The dataset used consisted of 150 instances corresponding to various shading and lighting conditions (dark, ambient, bright) for the shapes, which were displayed onto the thin-film photoconductor array using a micro-projector. As shown in FIG. 13, the testing dataset consisted of five shapes (el, triangle, cross, tee, ring) with various greyscale shading and three illumination conditions (dark, ambient, and bright). Conventional five-fold validation was performed to divide the dataset into training and testing subsets. In addition to providing the sensor outputs to the TFT weak classifiers for detection by the system, the raw sensor outputs were acquired for evaluation. In particular, the acquired data was used for training and classification by a MATLAB-implemented support vector machine (SVM) with radial-basis-function kernel, which is a widely used strong machine-learning classifier. The measured results, corresponding to true-positive (tp) and true-negative (tn) rates following each iteration of weak-classifier training, are shown in FIG. 10. Boosting of the TFT classifier is demonstrated by the performance improvement achieved with each iteration, eventually converging to high tp/tn (>85%/>95%). As seen, in all cases, the TFT-based classification system achieved performance close to that of an ideal SVM, with just 2-5 iterations, thus substantially reducing the signals required for image detection.

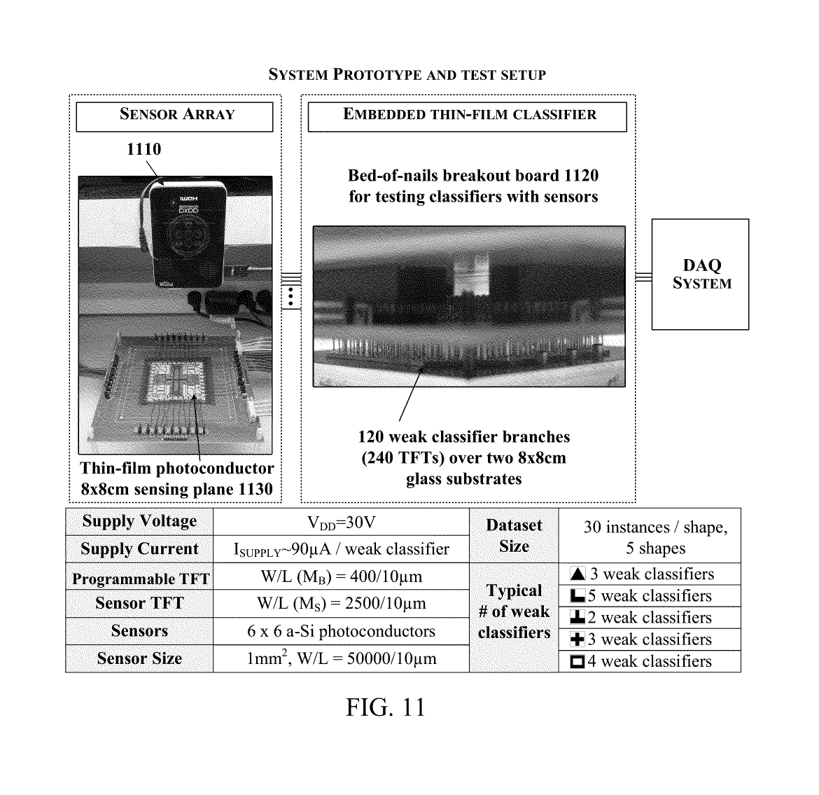

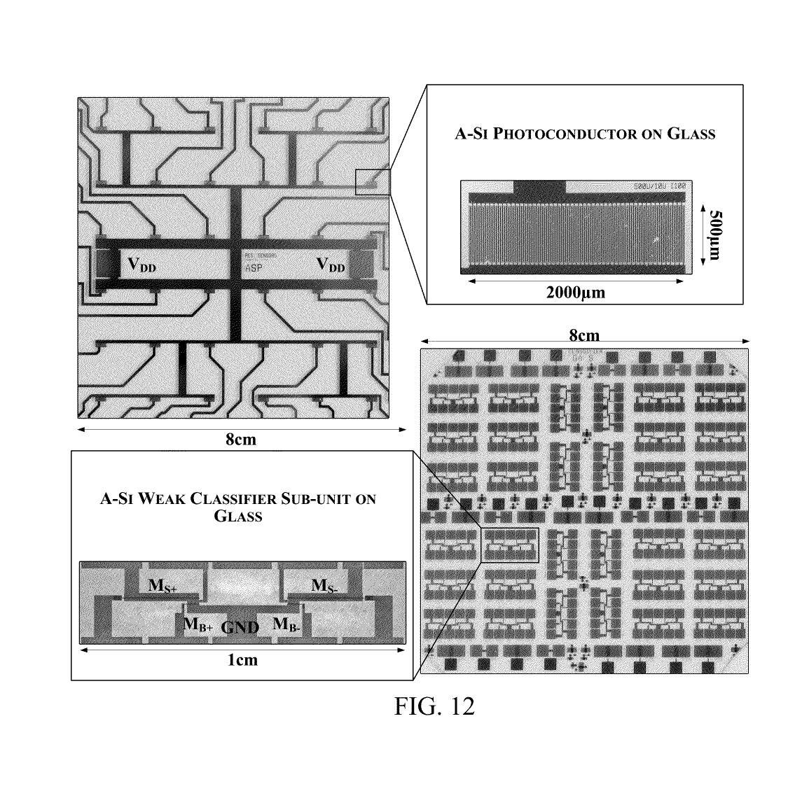

FIG. 11 shows the experimental setup and summarizes the classifier system performance. The micro-projector 1110 and breakout board 1120 used to facilitate testing of the thin-film sensor array 1130 and TFT classifiers are shown. Micrographs of fabricated a-Si photoconductors and TFT weak classifiers are in FIG. 12.

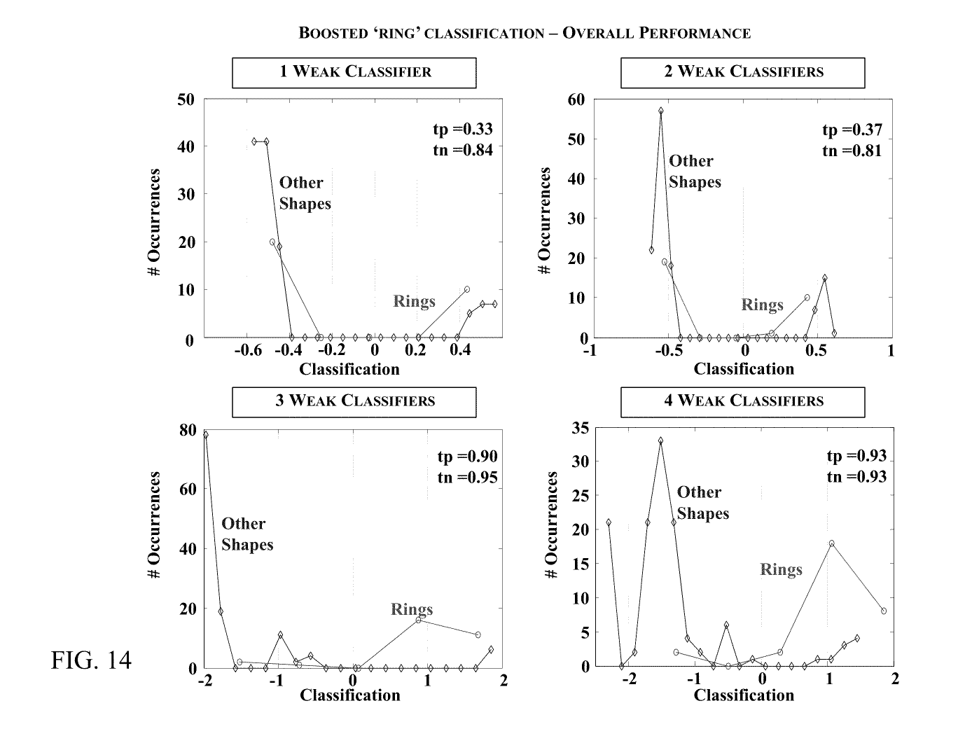

FIG. 14 shows the performance of the TFT classifier shown in FIG. 8, which employs a hardware-based implementation of the AdaBoost algorithm. FIG. 14 shows the measured histogram of the output from weighted voting over the testing dataset after each weak-classifier iteration. The two curves shown in each respective graph represent the two classes being classified (in this case, rings versus rest). The threshold of zero sets the boundary between the classes (i.e., rings versus others). With a single weak classifier, the performance achieved is extremely low. However, with only four weak classifiers, high performance is achieved, as illustrated by the improved separation between the histograms. Thus, in our prototype, the initial signals from thirty-six (36) sensor outputs (arranged in a 6×6 matrix) are reduced by at least a factor of nine (more in the case of other shapes).

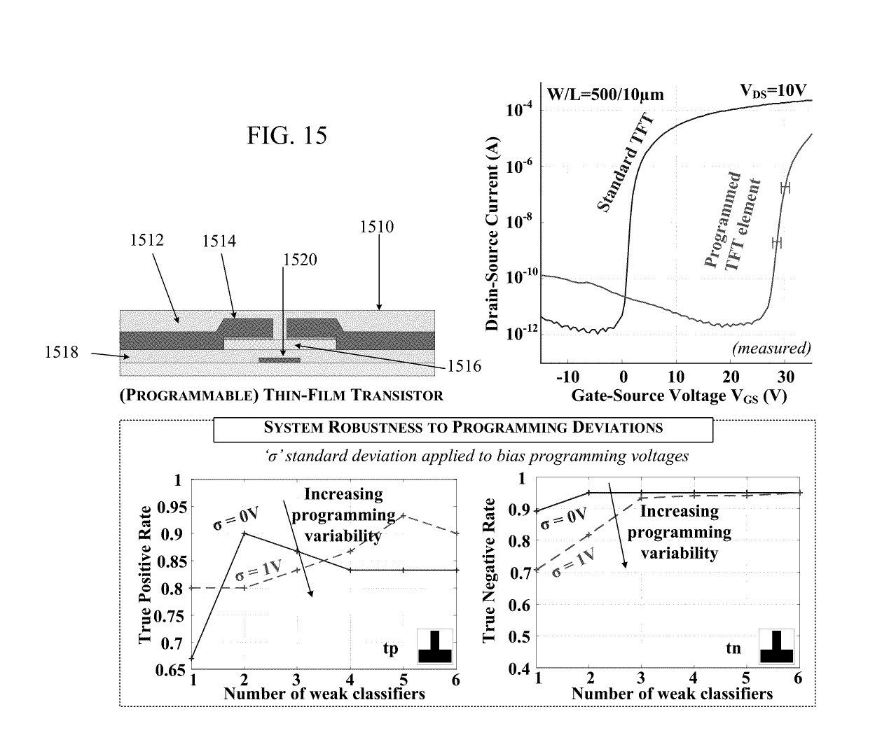

FIG. 15 shows a cross-sectional view of an exemplary thin-film transistor/programmable element. Specifically, thin-film transistor/programmable element 1510 comprises: passivation 1512, having electrical characteristic 280 nm SiNₓ, 180° C.; S/D Contact 1514, having electrical characteristic 50 nm Cr, 200 nm Al, 50 nm Cr and 30 nm n+a-Si:H, 180° C.; active region 1516, having electrical characteristic 150 nm a-Si:H, 180° C.; gate dielectric 1518, having electrical characteristic 280 nm SiNₓ, 180° C.; and, gate metal 1520, having electrical characteristic 20 nm Cr, 50 nm Al, 30 nm Cr.

One source of error in training weak classifiers is the variation in the resulting weighting biases applied through programming threshold voltage shifts. We measured this variation to have a small standard deviation of approximately 1 V around the intended voltage shift. FIG. 15 illustrates that the embedded classifier is robust to variations of that level as true positive/true negative performance is maintained in their presence.

As set forth above, one embodiment of the present invention is a thin-film sensing and classification system that can be used to perform, inter alia, classification and recognition of objects or images using large area-sensing arrays. Applications include imaging and other applications including image detection (x-ray, visible, IR), object detection on surfaces equipped with high density sensor planes, automatic sorting of objects (e.g. in a recycling plant) based on sensed physical properties (magnetic, absorption, shape . . . ), and other inferences over distributed sensors.

Said embodiment is able to perform high performance classification of images by using thin-film circuits embedded on the same backplane as a large number of (thin-film) sensors. This is achieved by leveraging a machine learning algorithm that helps to mitigate the effects of variability, failure and process defects common in thin-film technology.

Said embodiment comprises three main parts: a sensor array, thin-film electronic circuits, and a custom computational unit. An exemplary system was constructed with a photoconductor sensor array and thin-film circuits (fabricated using amorphous silicon thin-film transistors) in order to realize an image classification system, e.g., a shape classification system. Said exemplary system is capable of performing high performance classification, with performance close to that of a software-implemented strong classifier. This system can be used in commercial imaging applications that require the ability to discriminate between, for example, different object classes or other visual/physical features. The disclosed approach enables part of the computational classification process to be performed on the same substrate as the sensor array, reducing the interfacing complexity to high performance silicon-integrated circuits.

What is claimed is:

1. A thin-film sensing and classification system, comprising:
a plurality of thin-film image sensors;
a plurality of thin-film weak classifier circuits, each said classifier circuit coupled to each of said thin-film image sensors;
a plurality of threshold comparison circuits;
a weighted voter circuit, said weighted voter circuit coupled to said weak classifier circuits via said plurality of threshold comparison circuits; and
a summing circuit coupled to each of said weighted voter circuits, wherein said summing circuit is configured to generate a strong classifier decision output.

2. The system of claim 1, wherein said plurality of thin-film weak classifier circuits each comprise a plurality of subunits, each said subunit comprises a plurality of branches, and each said branch comprises two series connected thin-film transistors; and, wherein each said weak classifier generates differential outputs, and said weak classifier differential outputs are provided to said threshold comparison circuits.

3. The system of claim 1 further comprising a trainer circuit, wherein said trainer circuit is coupled to said output of said summing circuit, and wherein said trainer circuit is configured to provide feedback to said weak classifier circuits and to said weighted voter circuit.

4. The system of claim 3, wherein said plurality of thin-film weak classifier circuits each comprise a plurality of subunits, each said subunit comprises a plurality of branches, and each said branch comprises two series connected thin-film transistors; and, wherein each said weak classifier generates differential outputs, and said weak classifier differential outputs are provided to said threshold comparison circuit.

5. The system of claim 4, wherein at least one thin-film transistor in each said branch comprises a variable strength thin-film transistor, and wherein said trainer circuit is configured to provide feedback to each said weak classifier circuit via application of a programming voltage to each said variable strength thin-film transistor.

6. The system of claim 3, wherein said trainer circuit employs an Adaptive Boosting (AdaBoost) machine-learning algorithm to provide bias weights to said weak classifier circuits.

7. A thin-film sensing and classification system, comprising:
a plurality of thin-film sensors;
a backplane on which said thin-film sensors are mounted;
a plurality of thin-film electronic classifier circuits embedded on said backplane and coupled to said plurality of thin-film sensors; and
a computational unit coupled to said classifier circuits.

8. The system of claim 7, wherein said plurality of thin-film electronic classifier circuits each comprise a plurality of subunits, each said subunit comprises a plurality of branches, and each said branch comprises two series connected thin-film transistors; and, wherein each said thin-film electronic classifier circuit generates differential outputs, and said thin-film electronic classifier differential outputs are provided to said computational unit.

9. The system of claim 7, wherein said computational unit is configured to act as a weighted voter.

10. The system of claim 7, wherein said computational unit further comprises a trainer circuit, wherein said trainer circuit is configured to provide feedback to said classifier circuits.

11. The system of claim 10, wherein said computational unit employs an Adaptive Boosting (AdaBoost) machine-learning algorithm to provide bias weights to said classifier circuits.

12. The system of claim 8, wherein said computational unit further comprises a trainer circuit, wherein said trainer circuit is configured to provide feedback to said classifier circuits; and, wherein at least one thin-film transistor in each said branch comprises a variable strength thin-film transistor, and wherein said trainer circuit is configured to provide feedback to each said thin-film electronic classifier circuit via application of a programming voltage to each said variable strength thin-film transistor.

13. A sensing and classification system, comprising:
a plurality of sensors, each said sensor generating an output;
a plurality of weak classifiers, wherein each said weak classifier is connected to said output of each sensor of said plurality of sensors;
a weighted voter, wherein said weighted voter is connected to said plurality of weak classifiers; and
a summing circuit coupled to said weighted voter, wherein said summing circuit is configured to generate a strong classifier decision output.

14. The system of claim 13, further comprising a trainer, wherein said trainer is connected to said weighted voter, and wherein said trainer is configured to provide inputs to said plurality of weak classifiers and said weighted voter.

15. The system of claim 14, wherein said trainer is an embedded CMOS integrated circuit.

16. The system of claim 14, wherein said trainer employs an Adaptive Boosting (AdaBoost) machine-learning algorithm to provide bias weights to said weak classifiers.

17. The system of claim 14, wherein each said weak classifier comprises a plurality of thin-film weak classifier circuits; and, wherein each weak classifier circuit of said plurality of thin-film weak classifier circuits comprises a plurality of subunits, each said subunit comprises a plurality of branches, and each said branch comprises two series connected thin-film transistors; and, wherein each said weak classifier generates differential outputs, and said weak classifier differential outputs are provided to said weighted voter.

18. The system of claim 17, wherein at least one thin-film transistor in each said branch comprises a variable strength thin-film transistor, and wherein said trainer is configured to provide feedback to each said weak classifier circuit via application of a programming voltage to each said variable strength thin-film transistor.

19. The system of claim 14, wherein said trainer employs an Adaptive Boosting (AdaBoost) machine-learning algorithm to provide bias weights to said weak classifiers.
